(19) United States
(12) Patent Application Publication
(10) Pub. No.: US 2025/0305182 A1
(43) Pub. Date: Oct. 2, 2025

(54) IN-SITU PYROMETER FOR SILICON CARBIDE WAFER

(71) Applicant: VEECO INSTRUMENTS INC., Plainview, NY (US)

(72) Inventors: Ji-Dih Hu, San Jose, CA (US); Justin Raymundo, Somerset, NJ (US); Michael Chansky, Hillsborough, NJ (US); Sandeep Krishnan, Princeton Junction, NJ (US); Earl Marcelo, Springfield, NJ (US); Ying-Yi Hsu, Parsippany, NJ (US)

(73) Assignee: VEECO INSTRUMENTS INC., Plainview, NY (US)

(21) Appl. No.: 19/095,469

(22) Filed: Mar. 31, 2025

Related U.S. Application Data
(60) Provisional application No. 63/573,252, filed on Apr. 2, 2024.

(51) Int. Cl. C30B 25/16; C23C 16/32; C23C 16/458; C23C 16/48; C23C 16/52; C30B 29/36; G01J 5/00; G01J 5/0806; G01J 5/58

(52) U.S. Cl. CPC C30B 25/16; C23C 16/325; C23C 16/4583; C23C 16/48; C23C 16/52; C30B 29/36; G01J 5/0007; G01J 5/0806; G01J 5/58

(57) ABSTRACT

A chemical vapor deposition system (CVD) adapted to capture a temperature of a silicon carbide layer grown on a wafer includes a reaction chamber adapted to grow a silicon carbide layer epitaxially on wafers present within the chamber, a wafer carrier having a platform for carrying at least one wafer, a light source that emits radiation of a prescribed wavelength toward the wafer carrier, a first pyrometer coupled to the reaction chamber and configured to receive radiation emitted or reflected from the wafer and to measure radiation intensity of the prescribed wavelength, a reflectometer coupled to the pyrometer configured to receive and measure radiation of the prescribed wavelength reflected from the wafer in response to the radiation emitted by the light source, and an electronic controller configured to determine a temperature of the silicon carbide layer grown on the wafer using measurements of the first pyrometer and reflectometer.

### CROSS REFERENCE TO RELATED APPLICATION

The present application claims priority to and the benefit of U.S. patent application Ser. No. 63/573,252, filed Apr. 2, 2024, which is hereby expressly incorporated by reference in its entirety.

### TECHNICAL FIELD

The present technology is generally related to semiconductor fabrication technology and, more particularly, to an in-situ pyrometer for silicon carbide (SiC) wafers.

### BACKGROUND

During the fabrication of semiconductor wafers, numerous physical parameters, such as temperature, pressure and flow rate are monitored and regulated to achieve a desired crystal growth. Maintenance of a specific temperature during the wafer fabrication process is particularly important in order to achieve a high-quality semiconductor crystal. As the wafers are grown on a rotating apparatus, a non-contact method of measurement is required to accurately measure the temperature of the semiconductor wafers rotating at high speeds (e.g., greater than 1,000 RPM).

Non-contact temperature measurements of objects can be made using a pyrometer which measures radiation emitted from a target object. Pyrometers can be used to calculate the temperature of a physical body based on the emitted radiation power from the body and a physical characteristic of the body known as its emissivity. A body's emissivity is a measure of the ratio of the emitted radiation from a body to the incident radiation. The body's temperature can be computed given its emissivity (E) and emitted radiation power (P) according to Planck's equation:

$$P = {E}_{w} 2 π {C}_{1} {\int }_{0}^{∞} \frac{1}{{( λ T )}^{5} ( {𝕖}^{{C}_{2} / λ T} - 1 )} 𝕕λ \qquad ( 1 )$$

in which E_{w}=body emissivity (dependent on body color and surface characteristics) C₁, C₂=traceable universal constants (Planck's Spectral Energy Distribution), λ=radiation wavelength and T=body temperature.

From the emitted radiation power (P), the corresponding temperature of the body (T) can be accurately determined using the above equation if the emissivity of the body is known. Often, however, the emissivity of the semiconductor wafer changes during the course of the semiconductor growth process so as to complicate its temperature determination. Therefore, a real-time determination of the semiconductor wafer emissivity is necessary, in order to properly calculate the temperature of the semiconductor wafers during all phases of the semiconductor growth process. Reflectometry measurements can aid in this real-time determination according to the relation:

$$E = 1 - R \qquad ( 2 )$$

in which E is the emissivity and R is the reflectivity of the target.

Pyrometry and reflectivity measurements have been used effectively in capturing sufficiently accurate temperature measurements in reactor processes that occur in the 1000-1100° C. temperature range. In particular, at such temperature, an emissivity-corrected pyrometer at 949 nm (near infrared) can be used for such purposes. However, for semiconductor processing techniques, such as epitaxial growth of silicon carbide (SiC) for power devices, the required temperatures are much higher, e.g., at 1400-1700° C. At these elevated temperatures, the conventional emissivity-corrected pyrometry techniques suffer from considerable inaccuracy.

Another challenge to accurate temperature measurement is that the target wafer can be partially opaque, depending on the process temperature. In the case of a partially opaque wafer, the 949 nm pyrometer measures a weighted average of the wafer and carrier temperature, rather than the wafer temperature alone, introducing additional uncertainty into the wafer temperature measurement. Furthermore, in a hot wall reactor at elevated temperature, background stray radiation can drift due to parasitic coatings. The background radiation within the reaction chamber and parasitic deposition of SiC adds an additional layer of uncertainty or error.

What is therefore needed is a way to accurately measure wafer temperature over a range of temperatures, including elevated temperatures (˜1400-1700° C.) as well as lower temperatures (˜800-1100° C.) in order to capture accurate wafer temperatures during processes such as epitaxial growth that occur at high temperature as well as processes, such as wafer transfers, that typically occur at lower temperatures.

### SUMMARY

The present disclosure is directed to both a system and method and in particular, is directed to an in-situ pyrometer and chemical vapor deposition system (CVD) using such pyrometer, and to a method of capturing a temperature of a silicon carbide layer epitaxially grown on a wafer in a CVD reaction chamber using such pyrometer.

As mentioned, the present disclosure describes a chemical vapor deposition system (CVD) adapted to capture a temperature of a silicon carbide layer grown on a wafer. The system comprises a reaction chamber adapted to grow the silicon carbide layer epitaxially on wafers present within the chamber and a wafer carrier having a platform for carrying at least one wafer. The system also includes a light source that emits radiation of a first wavelength toward the wafer carrier, a first pyrometer coupled to the reaction chamber and configured to receive radiation emitted or reflected from the wafer and to measure radiation intensity of the first wavelength, and a reflectometer coupled to the pyrometer configured to receive and measure radiation of the first wavelength reflected from the wafer in response to the radiation emitted by the light source. An electronic controller is configured to determine a temperature of the silicon carbide layer grown on the wafer using measurements of the first pyrometer and reflectometer. The first wavelength is in a range of from 444 nm to 484 nm.

The present disclosure further describes a method of capturing a temperature of a silicon carbide layer epitaxially grown on a wafer in a CVD reaction chamber. The method comprises emitting radiation of a first wavelength onto the wafer during epitaxial growth of the silicon carbide layer detecting radiation of the first wavelength emitted and reflected from the wafer, and determining the temperature of the silicon carbide layer based on the detected radiation of the first wavelength emitted from and reflected from the wafer, wherein the first wavelength is in a range of from 444 nm to 484 nm. In one embodiment, the system includes two pyrometers. The first pyrometer emits and detects radiation of the first wavelength and the second pyrometer detects a second wavelength but can also be used in a detection mode to detect radiation of the second wavelength.

### BRIEF DESCRIPTION OF THE DRAWING FIGURES

The disclosure can be more completely understood in consideration of the following detailed description of various embodiments of the disclosure, in connection with the accompanying drawings, in which:

FIG. 1 is an absorption spectrum of N-type 4H SiC doped at a concentration level of approximately 10¹⁸/cm³.

FIG. 2 is a graph of the ratio between error in radiance intensity (dL/L) and error in temperature (dT/T) versus wavelength for pyrometry measurements.

FIG. 3 is a schematic diagram of a chemical vapor deposition (CVD) system according to an embodiment of the present disclosure.

FIG. 4 is a schematic diagram of a first embodiment of an apparatus for capturing a temperature of a wafer during epitaxial growth according to the present disclosure.

FIG. 5 is a schematic diagram of a second embodiment of an apparatus for capturing a temperature of a wafer during epitaxial growth according to the present disclosure.

While embodiments of the disclosure are amenable to various modifications and alternative forms, specifics thereof shown by way of example in the drawings will be described in detail. It should be understood, however, that the intention is not to limit the disclosure to the particular embodiments described. On the contrary, the intention is to cover all modifications, equivalents, and alternatives falling within the spirit and scope of the subject matter as defined by the claims.

### DETAILED DESCRIPTION OF CERTAIN EMBODIMENTS

The present disclosure describes a system and method for measuring the temperature of semiconductor wafers in CVD system, and in particular, provides a method for measuring the temperature of wafers as SiC is deposited and grown epitaxially on wafers at high temperatures of approximately 1400° C. to 1700° C. The disclosed system and method also provides for measuring wafers during transfer operations at relatively lower temperatures of 800° C. to 1100° C.

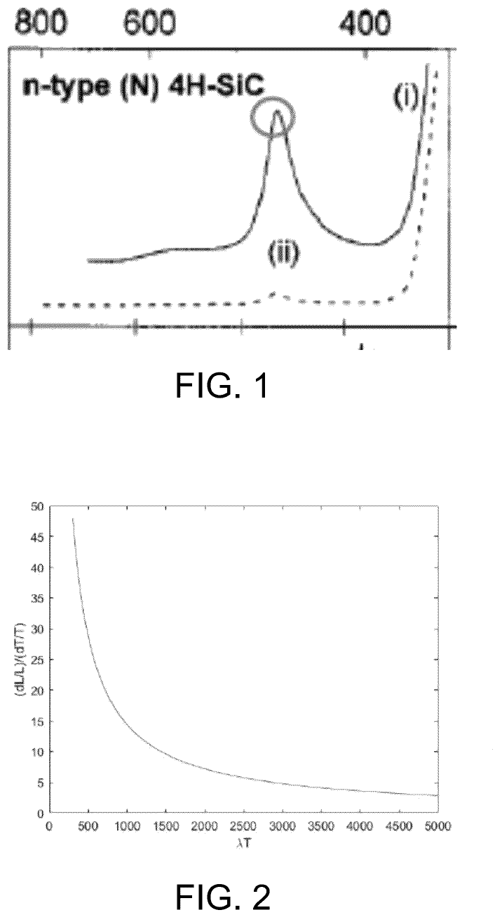

Embodiments of the system includes dual pyrometers: a first pyrometer is adapted to measure the temperature during epitaxial growth of a SiC layer while a second pyrometer is adapted to measure the temperature of the wafer during transfer operations. Measurement of wafer temperature during epitaxial growth makes use of a specific physical property of 4H SiC. FIG. 1 shows an absorption spectrum of N-type 4H SiC doped at a concentration level of approximately 10¹⁸, 10¹⁹/cm³. As can be seen in the figure, there is an absorption peak (highlighted) with a midlevel range of 444-484 nm. Accordingly, in this wavelength range the SiC is not transparent and therefore direct measurements of the SiC layer (wafer) temperature can be made. Use of a short wavelength of this range also provides the benefit of high accuracy. As shown in FIG. 2, depicting a graph of the ratio between error in radiance intensity (dL/L) and error in temperature (dT/T) versus wavelength, the ratio rapidly increases as wavelength decreases. That is, at shorter wavelengths, the ratio is higher, and the temperature error (dT/T) is compressed more during temperature conversion. For each single percentage error in measurement or emissivity value assumed, the temperature error is +1.15° K at 464 nm wavelength. This contrasts to the conventional wavelength used of approximately 949 nm, for which a one percent error in emissivity value corresponds to errors of +2.35° K. Thus, the lower wavelength (higher frequency) is associated with an improvement in accuracy of over a factor of two.

Longer wavelength radiation (e.g., 940-960 nm) is used to measure wafer temperature during wafer transfer which takes place at considerably lower temperatures because, in light of Planck's law, the amount (power) of emissions at shorter wavelengths (higher frequencies) is reduced at the lower temperature at which wafer transfer typically occurs (e.g., from 800° C. to 1100° C.). However, it will be appreciated that the preceding temperature range is merely exemplary and temperatures significantly below 800° C. are equally possible and would be characterized as being hot for doing a wafer transfer. Moreover, the requirement for accuracy and repeatability is less stringent for determination of wafer transfer temperature.

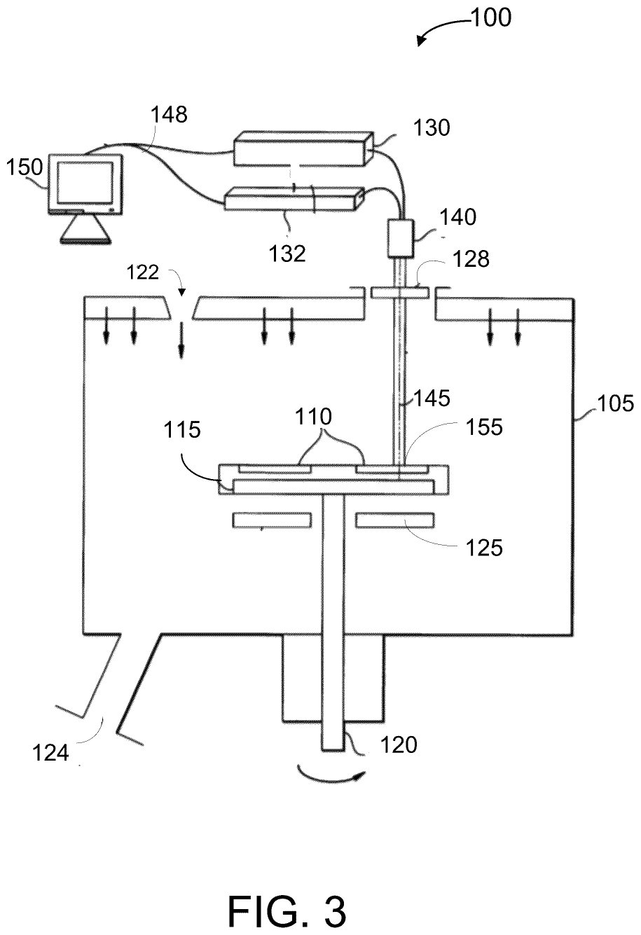

FIG. 3 is a schematic diagram of a CVD system 100 according to an embodiment of the present disclosure. A CVD reaction chamber 105 provides a housing for a number of components that are used to deposit injected reactant gasses upon semiconductor wafers 110 contained within the chamber. In the depicted embodiment, the gasses are used for purpose of epitaxial growth of a silicon carbide (SiC) layer (or GaN), but can be used for other purposes as well. The reaction chamber 105 (occasionally referred to herein as a “process chamber” or “reactor”), is configured to define a process environment space. The reactor region of the CVD system 100 is typically formed of vacuum-grade stainless steel or other suitable metal. The reaction chamber 105 is typically defined by a cylindrical wall with an upper end and a lower end remote therefrom. To prevent unwanted reactions within the reaction chamber 105, liners can be utilized to shield some of the metallic chamber components from the processing region.

The semiconductor wafers 110 are supported by a wafer carrier 115 which is attached to a rotating spindle 120. The spindle 120 provides for rotation of the wafer carrier 115 and is capable of rotating at velocities well above 1000 RPM. CVD reactant gasses are introduced into chamber 105 through an injector plate 122 and exhaust from the deposition process is expelled through an exhaust port 124. Heating units 125 are provided beneath wafer carrier 115 for heating the wafers 110 during the CVD process. A flow flange (not shown) can also be provided to introduce reactant gases into the reaction chamber 105 at a certain prescribed location. A viewport 128 is provided atop chamber 105 for optically viewing the activities occurring within the chamber.

As shown in the figure, positioned above the viewport 128 is a pyrometer/reflectometer 130. The pyrometer/reflectometer 130 is an instrument that measures temperature remotely by detection of radiation intensity from a target object. The pyrometer 130 can also be used in a reflectometer mode to measure amount of light intensity incident upon a target object that is reflected or scattered (for the sake of brevity the pyrometer/reflectometer is referred to below simply as a pyrometer). It is noted however, that in some embodiments the pyrometer and reflectometer can be separate devices. The pyrometer 130 is connected to a light emitting transmission head 140. Incident radiation emitted from light emitting head 140 travels along light path 145 to impinge upon the spinning wafer carrier 115. The pyrometer 130 is connected via electrical wiring 148 to a computing device 150 that is configured to receive and process real-time data output from the pyrometer. In preferred embodiments of the system 100, there are two pyrometers 130, 132. A first pyrometer 130 emits and detects radiation of a first wavelength. The second pyrometer can emit wavelength of a second wavelength but can also be used in detection mode to detect radiation of the second wavelength. The specifics of the wavelength ranges of the pyrometer(s) will be discussed further below.

The carrier 115 can hold multiple semiconductor wafers 110 so as to generally maximize the number of wafers placed on the carrier. The wafers 110 can be of any typical diameter such as 2 inch, 4 inch, 6 inch or 12 inch. The pyrometer 130 emits incident radiation along one or more light paths 145 that impinges upon a wafer at a measurement spot 155. As the wafer carrier 115 rotates, the measurement spot 155 remains in a fixed positioned at some radial distance from the rotating spindle. This provides measurement samples along a circular path of constant radius. The measurement spot 155 is typically less than six millimeters in diameter. The spot size of measurement spot 155 is preferably smaller in diameter than the diameter of the wafers 110. Due to the fact that the measurement spot is modified by the rotation of carrier 115, one condition for acquisition time can be formulated as:

$$τ < ( {D}_{w} - {D}_{p} ) / 2 * R * π * ω \qquad ( 3 )$$

in which τ is the parameter data acquisition time for the single measurements (in seconds), D_{w} is the wafer diameter (in inches), Dₚ is the pyrometer spot size with no rotation (in inches), R is the radius along which the measurement spot travels (in inches), and ω is the rotational speed of the wafer carrier (in RPM).

The condition above (3) helps ensure that the acquisition time is short enough that pyrometer measurements will indicate temperature on the wafer's surface rather than the temperature of the carrier. The measurements made by the pyrometer(s) provides the primary source for determining the wafer temperature. The measurements via the reflectometer mode are generally used to modify, refine or correct the measurements of the pyrometer mode in one or more of the wavelength channels as described further below. The pyrometer measurement is preferably calibrated to accurately determine temperature through received emissions via Planck's equation (1) above. Discrepancies that arise from background radiation are corrected using the reflectometer mode.

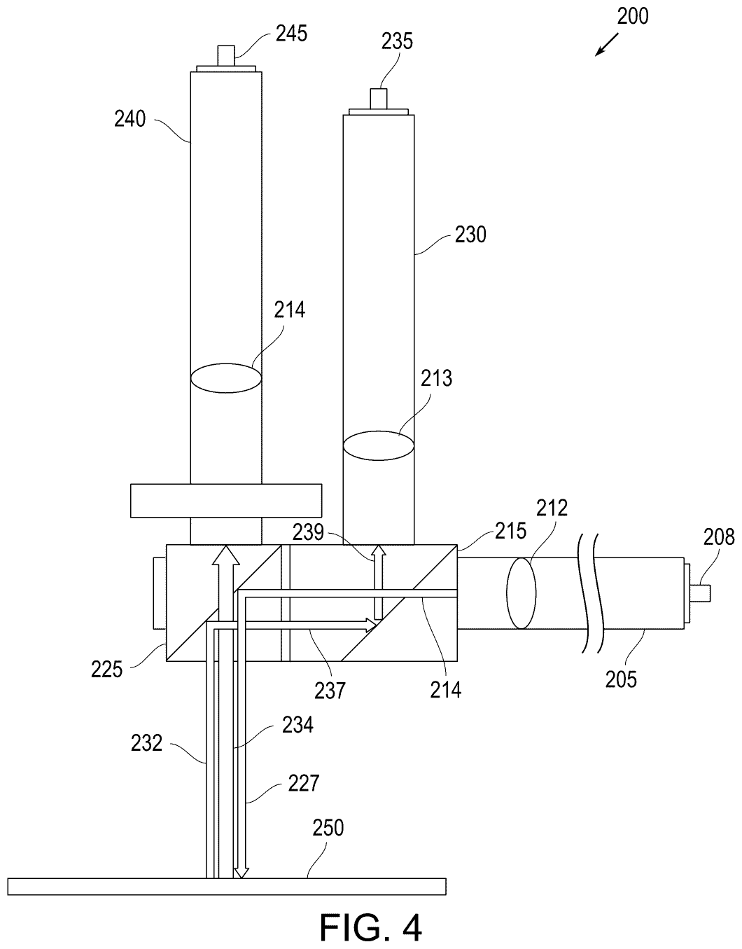

FIG. 4 is a schematic diagram of a first embodiment of a dual-channel pyrometer apparatus according to the present disclosure. The apparatus 200 includes a first lens tube 205 having a distal end to which a first light source 208 is coupled. The first light source 208 can be implemented using a light-emitting diode (LED) that emits pulses of radiation at a first wavelength. The first light source 208 can include a fiber coupler (not shown) through which the light source can receive light of the first wavelength from a remote source. In preferred embodiments, the first wavelength is in the range of 444-484 nm, which is in the visible blue part of the spectrum. In operation, the first light source 208 emits light through the length of the first lens tube 205. A first collimator 212 is positioned near the proximal end of the light tube 205 in order to collimate the radiation as it travels within the light tube 205 and is transmitted out of the lens tube 205. Light emerging from the collimator 212 travels along path 214 to a first beam-splitter 215. The first beam splitter 215 is designed to transmit radiation of the first wavelength further along path 214 to a second beam splitter 225, which is preferably dichroic. The second beam splitter 225 is designed to redirect radiation that is incident along path 214 onto a perpendicular path 227 out of the apparatus 200 toward the wafer 250.

Apparatus 200 further includes a second lens tube 230 and a third lens tube 240 aligned at right angles to the first lens tube 205. The second lens tube 230 is coupled at a proximal end to the first beam splitter 215 and extends to a distal end having a first pyrometer 235. The third lens tube 240 is coupled at a proximal end to the second beam splitter 225 and extends to a distal end having a second pyrometer 245. The pyrometers 235, 245 are radiation sensors that can be implemented using silicon photodiode detectors. This implementation saves costs as silicon photodiodes are less expensive in comparison to photomultiplier tubes, which are also commonly used in pyrometers.

The wafer 250 in the reaction chamber at high temperature emits black body radiation at the high temperature and in addition, reflects a portion of the radiation of the incoming first wavelength that impinges upon the along optical path 227. The wavelength of radiation emitted/reflected depends on the temperature of the wafer per equation (1) above. During epitaxial growth at high temperature, the wafer emits radiation at or near the first wavelength and also reflects a portion of radiation of this wavelength incoming along optical path 227. The emitted/reflected radiation of the first wavelength is shown as first reverse optical path 232 which extends between the wafer 250 and the second beam splitter 225. Alternatively, during wafer transfer operations, the radiation emitted by the wafer reflects the lower temperature and a lower, second wavelength of radiation is emitted. The second wavelength is in the range of 940-960 nm, although the accuracy of the second wavelength is not as critical as the accuracy of the first wavelength. The emission path of radiation of the second wavelength from the wafer toward the second beam splitter is shown as second reverse optical path 234. While optical paths 232, 234 are shown as distinct in order to represent different frequencies, the two paths 232, 234 can overlap spatially.

When radiation of the first wavelength transmitted along optical path 232 reaches the second beam splitter 225, a portion of the radiation is redirected perpendicularly along a new optical path 237 into the first beam splitter 215. The radiation of the first wavelength is again redirected by the first beam splitter 215 along another optical path 239 which is directed through the second lens tube 230 and toward pyrometer 235. Pyrometer 235 detects an intensity of the first wavelength that it receives.

When radiation of the second wavelength along optical path 234 reaches the second beam splitter 225, a portion of the radiation is transmitted through the beam splitter into the third lens tube 240 and toward pyrometer 245. Pyrometer 245 detects an intensity of the second wavelength that it receives.

Both the second and third lens tubes 230, 240 preferably include collimators 213, 214, respectively, to help minimize background thermal emissions that can vary in a hot-wall reactor for SiC epitaxy, since parasitic deposition is typically a notable problem in such reactors.

In the depicted embodiment, pyrometer 235 can comprise a pyrometer device that acts as both a pyrometer and reflectometer as discussed further below. However, as noted above, this need not be the case, and separate pyrometer and reflectometers can be used. In the latter case, signals received can be split and received at a pyrometer and a reflectometer housed in separate enclosures. In either case, the pyrometer device is adapted to detect and measure the amount of radiation emitted from the wafers in accordance with equation (1) above, while the reflectometer (mode or device) is adapted to measure the amount of incident radiation that is reflected from the wafer. More specifically, the reflectometer determines reflectance (R) of the wafer from which the emittance (E) of the wafer, which can change with variation in temperature, can be determined via equation (2) above. The determination of the emittance then can be used to modify the initial reading of the pyrometer. Notably, in apparatus 200, the reflectometer is used only with radiation only through the first channel. Therefore, in the depicted embodiment, the reflectometer is configured to measure the radiation reflected from the wafer solely at the first wavelength. This measure further increases the accuracy of measurements made of the epitaxial growth of the 4H SiC layer at high temperature.

As mentioned, the system described herein (e.g., system of FIG. 4) includes a number of collimators that are used to minimize stray radiation according to an embodiment of the disclosure. Conventionally, pyrometers are focused to have a minimum spot size on the target surface. However, this technique allows stray radiation to be picked up by the pyrometer. According to embodiments of the present disclosure, stray radiation is minimized by directing the incident beam that is directed to the target wafer surface through a collimator. The beam exiting the collimator is shaped in the form of a cylinder rather than a cone converging on a focused point. This makes it more difficult for light originating outside of the beam from reaching the detector. The beam exiting the collimator can be approximately 2 mm in diameter. This diameter is larger than typical diameters of a focused beam, but the beam is of sufficient intensity that the larger area of the beam does not affect ultimate temperature measurements. In addition, as shown in FIG. 4, a returning beam emitted/reflected from the wafer is also directed through a collimator en route to the pyrometer. With a specular and opaque wafer very little stray radiation from the background is picked up via reflection or scattering. As noted, 4H SiC is substantially opaque to the first wavelength (444-484 nm) at a doping level of approximately 10¹⁸/cm³. The absorption coefficient at this wavelength is approximately 40/cm at room temperature and increases as the temperature rises.

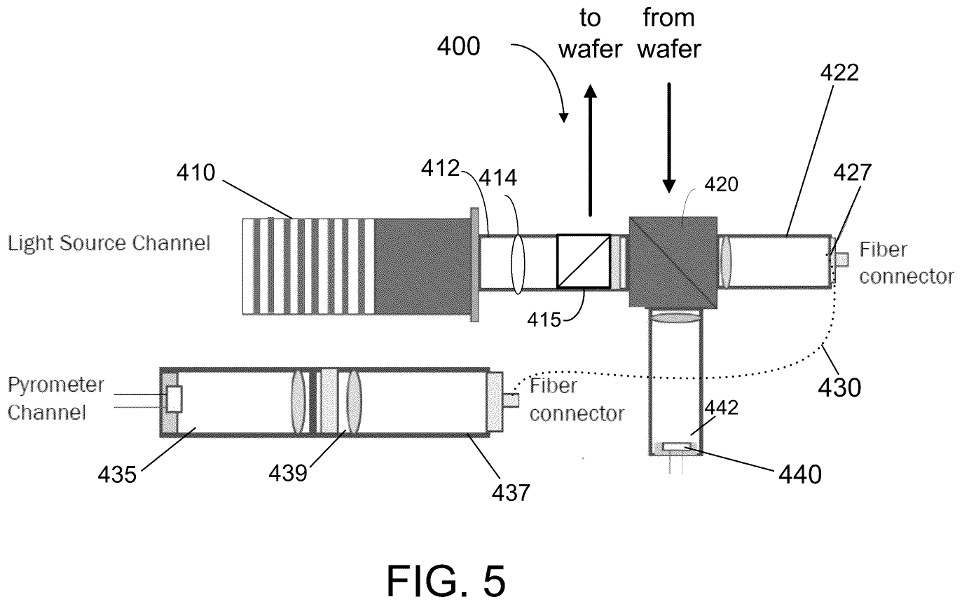

FIG. 5 is a schematic diagram of another embodiment of a dual-channel pyrometer apparatus according to the present disclosure that includes fiber connections. In this second embodiment, the apparatus 400 includes a light source section 410 that emits radiation at the first wavelength. The light source is coupled to a distal end of a lens tube 412 having collimating optics 414. The proximal end of the lens tube 412 is coupled to a first beam splitter 415. Radiation emitted by the light source 410 that reaches the first beam splitter 415 is redirected toward the wafer as shown in the figure. As discussed above, depending upon the temperature of the wafers (and the processes that they are undergoing), radiation is emitted and reflected from the wafers back towards the beam splitter. During high temperature processes, such as SiC epitaxial growth, radiation of the first wavelength is redirected by a second beam splitter 420 perpendicularly along a first optical path through a second lens tube 422. At the distal end of the second lens tube 422 is a fiber connector 427. Radiation that reaches the fiber connector can then travel along optical fiber 430 to a first pyrometer 435 via a corresponding fiber connector 437 and optics 439. The first pyrometer detects the intensity of received radiation of the first wavelength.

During lower temperature processes such as wafer transfer, radiation of the second wavelength is similarly emitted from the wafers back toward beam splitter 420. Upon reaching the beam splitter 420, a portion of the radiation of the second wavelength passes through the beam splitter into the lens tube 442 of a second pyrometer 440. The second pyrometer detects the intensity of received radiation of the second wavelength.

The embodiment depicted in FIG. 5 allows the sensitive electronic components of the first pyrometer to be separated from the CVD reaction chamber via the use of fiber optic cables. This is useful as the high temperatures of the reaction chamber can potentially affect the electronics of the pyrometer.

Referring again to FIG. 3, the computing device controls operation of the various components of the system. In certain embodiments, the computing device sends signals to cause the LED sources of the dual-channel pyrometer apparatus to pulse and to cause the detectors to take measurements in a triggered mode. In this manner, alternating measurements can be taken when the LED is turned on and off. The computing device is configured to determine differences in temperature measured in the on and off cycles. When the system is properly calibrated, the difference between the on/off cycles can be translated into reflectance. This is one way in which the pyrometer can be controlled to act in “reflectometer” mode. Additionally, the off-cycle data enables calculation of the wafer temperature, and emissivity derived from the reflectance is used to compensate for changes in wafer emissivity.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112 (f) are not to be invoked unless the specific terms “means for” or “step for” are recited in a claim.

What is claimed is:

1. A chemical vapor deposition system (CVD) adapted to capture a temperature of a silicon carbide layer grown on a wafer, the system comprising:
a reaction chamber adapted to grow the silicon carbide layer epitaxially on wafers present within the chamber;
a wafer carrier having a platform for carrying at least one wafer;
a light source that emits radiation of a first wavelength toward the wafer carrier;
a first pyrometer coupled to the reaction chamber and configured to receive radiation emitted or reflected from the wafer and to measure radiation intensity of the first wavelength;
a reflectometer coupled to the pyrometer configured to receive and measure radiation of the first wavelength reflected from the wafer in response to the radiation emitted by the light source; and
an electronic controller configured to determine a temperature of the silicon carbide layer grown on the wafer using measurements of the first pyrometer and reflectometer,
wherein the first wavelength is in a range of from 444 nm to 484 nm.

2. The CVD system of claim 1, wherein the light source, reflectometer and pyrometer are activated when the temperature of the chamber is elevated during a phase of epitaxial growth.

3. The CVD system of claim 1, further comprising:
a second pyrometer coupled to the reaction chamber and configured to receive radiation of a second wavelength that is longer than the first wavelength also emitted from the wafer, wherein the controller is configured to determine a temperature of the wafer during transfer operations based on measurements of the second pyrometer.

4. The CVD system of claim 1, wherein the first pyrometer and the reflectometer are enclosed within a single housing.

5. The CVD system of claim 2, wherein the elevated temperature of the reaction chamber during epitaxial growth is between 1400° C. and 1700° C.

6. The CVD system of claim 3, wherein the temperature of the wafer during transfer operations is between 800° C. and 1100° C.

7. The CVD system of claim 1, wherein the silicon carbide is of a 4H SiC type which has an absorption peak shorter than 500 nm.

8. The CVD system of claim 7, wherein the 4H SiC layer is doped at a level of approximate 10¹⁸/cm³.

9. The method of claim 1, wherein the light source includes a collimator for collimating the radiation directed onto the wafer.

10. A method of capturing a temperature of a silicon carbide layer epitaxially grown on a wafer in a CVD reaction chamber, the method comprising:
emitting radiation of a first wavelength onto the wafer during epitaxial growth of the silicon carbide layer;
detecting radiation of the first wavelength emitted and reflected from the wafer;
determining the temperature of the silicon carbide layer based on the detected radiation of the first wavelength emitted from and reflected from the wafer,
wherein the first wavelength is in a range of from 444 nm to 484 nm.

11. The method of claim 10, further comprising:
detecting radiation of a second wavelength emitted from the wafer during a wafer transfer operation;
determining the temperature of the wafer during the transfer operation on the detected radiation of the second wavelength.

12. The method of claim 11, wherein detection of the radiation of the first wavelength is performed when a temperature within the reaction chamber is between 1400° C. and 1700° C.

13. The method of claim 11, wherein detection of the radiation of the section wavelength is performed when a temperature within the reaction chamber is between 800° C. and 1100° C.

14. The method of claim 11, wherein the silicon carbide is of a 4H SiC type which has an absorption peak shorter than 500 nm.

15. The method of claim 14, wherein the 4H SiC layer is doped at a level of approximate 10¹⁸/cm³.

16. The method of claim 10, further comprising collimating the radiation of the first wavelength emitted onto the wafer.
